(19) United States
(12) Patent Application Publication
(10) Pub. No.: US 2004/0140549 A1
(43) Pub. Date: Jul. 22, 2004

(54) Wiring structure and its manufacturing method

(76) Inventor: Fumio Miyagawa, Nagano-shi (JP)

Correspondence Address: STAAS & HALSEY LLP, SUITE 700, 1201 NEW YORK AVENUE, N.W., WASHINGTON, DC, 20005, US

(21) Appl. No.: 10/476,844

(22) PCT Filed: Mar. 20, 2003
(86) PCT No.: PCT/JP03/03468

(30) Foreign Application Priority Data
Mar. 28, 2002 (JP) 2002-91746

(51) Int. Cl. H01L 23/48

(52) U.S. Cl. 257/700; 257/690

(57) ABSTRACT

A wiring structure having connection wiring for electrically connecting elements to one another or one element to another constituent element. The connection wiring is a sintered product formed by depositing a paste of conductive fine particles comprising conductive fine particles having a particle diameter of 100 nm or below dispersed in a dispersant, on an electrically insulating base, in accordance with a predetermined pattern, and then sintering a wiring precursor so formed. The conductive paste can be preferably deposited through an ink jet printing method. Further, after one or more cells having an arbitrary configuration or a basic configuration on the base, the conductive fine particle paste may be deposited to a surface of the cell, so that a connection wiring is three-dimensionally formed. When the cells are combined with one another, an integrated electronic device and a multi-layered wiring board can be compactly formed.

### TECHNICAL FIELD

This invention relates to a wiring structure, useful for producing semiconductor devices and other electronic devices, which has a compact and high-density wire distribution and also can be produced easily and is excellent in reliability, and to a production method for such a wiring structure.

### BACKGROUND ART

A wide variety of semiconductor devices have been suggested and various methods have been employed to package such a variety of semiconductor devices onto wiring substrates. A basic technology for producing semiconductor devices or for packaging semiconductor devices is an electric connection technology for electrically connecting active elements such as semiconductor elements (for example, IC chips, LSI chips, etc) or passive elements such as capacitors, resistors, etc with a wiring substrate or electrically connecting wiring patterns to one another. In other words, the basic technology is the one that forms a connection wiring for electric connection.

In a wiring substrate to which semiconductor elements are mounted, a wiring pattern is formed into a multi-layered structure by means such as a build-up method, a print-up method, and the like. Methods for forming the wiring pattern include a photolithographic method, a transfer method, a through-mask printing method and a plating technology. Furthermore, methods for electrically connecting the wiring patterns between discrete layers by through-hole plating or via-holes have been employed. To electrically connect the semiconductor elements and the wiring patterns, a wire bonding method and a flip chip method have been employed.

An example of a package having semiconductor elements mounted thereon is illustrated in FIG. 1. Generally, a semiconductor element (for example, an LSI chip) 110 is mounted onto a wiring substrate (for example, a glass-epoxy substrate) 111 through a die bonding paste or a die bonding film 113 as shown in FIG. 1, and the semiconductor element 110 and the wiring substrate 111 are electrically connected through bonding wires 114 made of gold (Au), for example. The semiconductor element 110 and the bonding wire 114 are sealed with an insulating resin 112 such as an epoxy resin to protect the semiconductor package as a whole.

FIG. 2 shows an example of a so-called “SON type” lead frame package fabricated by use of the wire bonding method in the same way as the example shown in FIG. 1. In the case of the package shown in this drawing, lead terminals 115 are fixed to the semiconductor element 110 through a resin film 116, and then the semiconductor element 110 and the lead terminals 115 are electrically connected through bonding wires 114, and an insulating resin 112 seals a semiconductor package including the semiconductor element 110 as a whole.

Incidentally, as the performances of both semiconductor elements and semiconductor devices have become higher and their sizes have become smaller, extremely small products such as a chip size package (CSP) have now been produced. Therefore, the wiring patterns formed on the wiring substrate, etc, have come to possess a higher density. It is therefore desirable to form connection wiring without using the wire bonding method described above that inevitably requires a large wiring space and troublesome operations for the formation and cannot avoid the problem of disconnection.

In addition, as the size and thickness of the semiconductor elements or circuit components have been reduced, a large number of modular products, in which a plurality of semiconductor elements are stacked or mounted with circuit components, have been provided. As a result, a connection form that allows wiring having a higher density and more three-dimensional wiring and can easily cope with various product forms has been required for the electric connection wires.

FIG. 3 shows an example of a semiconductor package in which a semiconductor element and a wiring pattern of a circuit substrate are connected by a flip chip method. In the case of a ball grid array (BGA) type semiconductor package shown in the drawing, the wiring substrate 120 and the semiconductor element 110 are electrically connected through a plurality of bumps (for example, Au bumps) 121, and solder bumps 122 are provided as external connection terminals to the wiring substrate 120. In comparison with the wire bonding method, the flip chip method can make a greater contribution to the reduction of the size and thickness of the device and can solve the problem of disconnection. However, the flip chip method cannot solve the problem of the troublesome production, and therefore a method that can more easily establish electric connection has been desired.

FIG. 4 shows an example of a package that includes rerouted wiring connections to reduce the size and the thickness. The semiconductor package shown in the drawing can be generally fabricated through the steps of forming a first insulating resin layer 131 on one of the surfaces of the semiconductor element, forming via-holes at predetermined positions of the first resin layer 131 to penetrate through the resin layer 131, filling an electric conductor (for example, Cu) into the via-holes by plating to form a buried wiring layer 132, forming a wiring layer 133 in a predetermined pattern on the surface of the first resin layer 131, disposing solder bumps 135 as external connection terminals, and sealing the package as a whole with an insulating resin 134. However, because the production steps are complicated, a method that can conduct rerouted wiring connection with a reduced number of steps has been desired.

The connection wiring for electric connection is of utmost importance not only for the production of the semiconductor packages described above but also for other technical fields. For example, the wiring substrate is generally used as a multi-layered wiring substrate so as to reduce the size of devices and to improve their functions. Further, in the multi-layered wiring substrate, wiring patterns are formed in multiple layers by the build-up method, the print-up methods, and the like, as described above. However, the formation of the wiring patterns by these methods all need complicated technologies such as the photolithographic method, the transfer method, the through-mask printing method, the plating method, etc. Therefore, a method capable of forming more easily and with higher accuracy the multi-layered wiring patterns has been desired.

FIG. 5 shows an example of the multi-layered wiring substrate fabricated by the build-up method. The multi-layered wiring substrate shown in the drawing can be produced by the steps of forming an insulating film 141 made of a polyimide resin, for example, to a predetermined thickness on a semiconductor element (for example, a system LSI) 110, opening via-holes by the photolithographic method, and filling the via-holes with copper (Cu) plating to form micro via-holes 142. The micro via-holes have a diameter of about 80 μm and a pitch of about 150 μm. After the micro via-holes 142 are formed, a resist (not shown) is applied at a thickness of about 60 μm to form a resist film. The resist film is patterned and a wiring layer (wiring pattern) 143 is formed through copper plating. When the process steps from the formation of the insulating film 141 to the formation of the wiring layer 143 are repeated, there is obtained the multi-layered wiring substrate in which the insulating film and the wiring pattern are alternately stacked and the wiring patterns are electrically connected with one another through the micro via-holes. The size of the wiring pattern is a line-and-space of about 50/50 μm.

FIG. 6 also shows an example of the multi-layered wiring substrate fabricated by the build-up method. The insulating film 141 and the wiring pattern 143 are alternately stacked on the semiconductor element 110, and the wiring patterns are electrically connected to one another through filled via-holes 144. In the case of the multi-layered wiring substrate shown in the drawing, laser drilling is employed in place of the step of forming the via-holes by photolithography to reduce the size of the substrate. In the resulting laser via-holes, a diameter of about 50 μm and a pitch of about 100 μm can be obtained. A dry film having a thickness of 30 μm can be used as a mask for forming the respective wiring patterns. Consequently, the wiring patterns can be formed with a line-and-space of about 20/20 μm. It can be seen, by comparing FIG. 5 with FIG. 6, that the multi-layered wiring substrate shown in FIG. 6 is smaller and more compact.

When the multi-layered wiring substrate is produced by the prior art build-up method and print-up method as described above, the resulting wiring pattern has a limit (generally, about 20 to 50 μm) with regard to the line width. Therefore, a method capable of forming a finer wiring pattern more easily and with higher yield has been desired.

As still another example of the conventional multi-layered wiring substrate, FIG. 7 shows a semiconductor package produced by an embedding mount technology (EMT). In the case of the semiconductor package shown in the drawing, the multi-layered circuit substrate is first formed by alternately stacking the insulating film 141 and the wiring pattern 143. Next, two semiconductor elements 110 having different sizes are mounted to one of the surfaces of the circuit substrate after level adjustment. Finally, the substrate and the elements are sealed as a whole with an insulating resin. In the case of the semiconductor package of this type, the production is troublesome due to the complicated construction of the package, and therefore a method capable of forming a more compact package, easily and with higher yield, has been desired.

### DISCLOSURE OF THE INVENTION

The object of the invention is to solve the prior art problems described above.

It is one object of the invention to provide a wiring structure that has extremely fine connection wirings in a high density and does not invite the problems of disconnection and short-circuit.

It is another object of the invention to provide a wiring structure that has three-dimensionally formed connection wiring and is useful for reducing sizes and thickness of semiconductor devices and other devices and for improving their functions.

It is still another object of the invention to provide a wiring structure that can easily cope with various product forms.

It is still another object of the invention to provide a method for producing easily and at a high yield the wiring structure described above.

These and other objects of the invention will be easily understood from the following detailed descriptions of the invention.

According to an aspect of the invention, there is provided a wiring structure comprising connection wiring for electrically connecting elements to one another or one element to another constituent element, wherein the connection wiring is a sintered product formed by depositing a paste of electrically conductive fine particles comprising electrically conductive fine particles having a particle diameter of 100 nm or below dispersed in a dispersant on an electrically insulating base in accordance with a predetermined wiring pattern, and then sintering a wiring precursor so formed.

According to another aspect of the invention, there is provided a method for producing a wiring structure comprising connection wiring for electrically connecting elements to one another or one element to another constituent element, which comprises the steps of:

depositing a paste of electrically conductive fine particles comprising electrically conductive fine particles having a particle diameter of 100 nm or below dispersed in a dispersant on an electrically insulating base in accordance with a predetermined wiring pattern; and

heating and sintering a wiring precursor so formed at a predetermined temperature to form the connection wiring.

As will be explained below in detail, the invention is directed to form the connection wiring by applying the conductive paste to the wiring substrate, etc, in accordance with a predetermined pattern. The invention uses a paste of electrically conductive fine particles (hereinafter, briefly called “conductive paste” or “fine particle paste”) prepared by dispersing electrically conductive fine particles having a particle diameter of 100 nm or below in a dispersant, as the conductive paste. The paste of the electrically conductive fine particle is applied in accordance with a pattern of wiring to be formed onto a surface of an insulating layer, an insulating film, an inter-level insulating film or other electrically insulating elements that has already been formed, and is then heated to a predetermined temperature to make sintering. In this way, the connection wiring, that can be also called conductor elements, can be completed.

The conductive fine particle paste may be, as such, applied to a planar base such as an insulating film, or may be preferably applied to a surface of cell-like supports (hereinafter, briefly called “cells”) formed of a molding material having an electrically insulating property and capable of being applied in an arbitrary shape by use of a dispenser, or the like. When the conductive paste is applied to a surface of the cell having the previously given shape, the connection wiring extending three-dimensionally can be easily formed without calling for the large number of process steps that have been required in the past.

The application of the electrically conductive fine particle paste can be made by using conventional methods. It is recommended, however, to use a paste supplying apparatus such as a dispenser or to allow the conductive paste to fly onto the surface of the cell, for coating, in accordance with an ink jet system. The conductive fine particle paste can be applied into a desired pattern and to a desired film thickness by either of the methods without using mask means that has been required customarily in the prior art technologies.

The cell made of the electrically insulating material can be advantageously used in various forms or configurations. For example, the cell may already have a configuration suitable for forming a wiring pattern thereon, or may be formed in situ to have such a configuration. Alternatively, the cell may be formed by the steps of preparing basic cells formed into a predetermined shape in the form of basic cells, and arranging two or more basic cells on a surface of a support for forming a connection wire such as a semiconductor chip or a wiring substrate in the form suitable for forming thereon a wiring pattern. According to either method, the freedom is great when a three-dimensional connection wire is formed.

A basic cell made of a dielectric material, a basic cell made of a material for adjusting a heat conduction coefficient and a basic cell made of a material for adjusting a thermal expansion coefficient may be used in an arbitrary combination as the basic cell, besides the basic cell made of the electrically insulating material. When such a method is employed, a wiring structure requiring a higher function and a more complicated construction can be easily completed.

Furthermore, a wiring structure having a three-dimensional structure and high functions and comprising insulating films and connection wires can be completed by combining tablets for forming wiring (called also “micro cells” or “conductive micro cells”) that are obtained by processing the conductive fine particle paste by printing, or the like with tablets for forming insulating films (called also “micro cells” or “insulating micro cells”) obtained by similarly processing an electrically insulating material by printing, or the like.

### BRIEF DESCRIPTION OF THE DRAWINGS

FIG. 1 is a sectional view of the prior art semiconductor package produced by a wire bonding method;

FIG. 2 is a sectional view of the prior art lead frame package produced by a wire bonding method;

FIG. 3 is a sectional view of the prior art semiconductor package produced by a flip chip method;

FIG. 4 is a sectional view of the prior art semiconductor package to which rerouted wiring connection was applied;

FIG. 5 is a sectional view of the prior art multi-layered wiring substrate produced by a build-up method;

FIG. 6 is a sectional view of the prior art multi-layered wiring substrate produced by a build-up method different from the method shown in FIG. 5;

FIG. 7 is a sectional view of the prior art semiconductor package produced by an embedding mount technology;

FIGS. 8A to 8D are sectional views showing, in sequence, a method for forming connection wiring by an ink jet system;

FIG. 9 is a sectional view showing a free cell method used for forming connection wiring according to the invention;

FIG. 10 is a sectional view showing a basic cell method used for forming connection wiring according to the invention;

FIG. 11 is a sectional view showing a micro cell method used for forming connection wiring according to the invention;

FIG. 12 is a sectional view of a semiconductor package of the present invention produced without using a wire bonding method;

FIG. 13 is a sectional view of a semiconductor package of the present invention produced without using the wire bonding method;

FIG. 14 is a sectional view of a semiconductor package produced by incorporating a wiring structure of the invention that can be in place of the prior art lead frame package;

FIG. 15 is a sectional view of a semiconductor package of the present invention produced without using a flip chip method;

FIG. 16 is a sectional view of a semiconductor package to which rerouted wiring connection was applied according to the invention;

FIG. 17 is a sectional view of a multi-layered wiring substrate produced by using a build-up method according to the invention;

FIG. 18 is a sectional view of a semiconductor package produced by using an embedding mount technology according to the invention;

FIGS. 19A to 19E are sectional views showing, in sequence, a method for forming connection wiring by using a free cell method according to the invention;

FIG. 20 is a perspective view showing a connection state of a wiring pattern and connection wiring according to the invention;

FIGS. 21A and 21B are sectional views showing, in two stages, a method for forming connection wiring by using a free cell method according to the invention;

FIGS. 22A and 22B are sectional views showing, in two stages, a method for producing a semiconductor device by stacking two semiconductor elements according to the invention;

FIGS. 23A to 23F are sectional views showing, in sequence, a method for forming multi-layered connection wiring according to the invention;

FIGS. 24A to 24H are sectional views showing, in sequence, a method for forming connection wiring by using a basic cell method according to the invention;

FIG. 25 is a plan view of a multi-layered wiring substrate obtained by stacking basic cells in multiple layers;

FIG. 26 is a sectional view showing an example of the structure of the cell integration module produced using the basic cells;

FIG. 27 is a sectional view showing another example of the structure of the cell integration module produced using the basic cells;

FIG. 28 is a perspective view showing an example of the structure of the cell integration module board produced using the basic cells;

FIG. 29 is a perspective view showing a method for forming connection wiring by using a micro cell method according to the invention;

FIG. 30 is a sectional view of a wiring structure having a construction similar to the shown in FIG. 29;

FIGS. 31A to 31E each is a sectional view showing a semiconductor package having a wiring structure of the invention assembled therein;

FIG. 32 is a sectional view of a semiconductor package produced by incorporating a wiring structure of the invention that can be used in place of the prior art lead frame mold package;

FIG. 33 is a sectional view of a semiconductor package of the present invention produced without using a flip chip method;

FIG. 34 is a sectional view of a VMT board having a wiring structure of the invention assembled therein;

FIG. 35 is a sectional view of a display VMT board having a wiring structure of the invention assembled therein and a built-in DMFC fuel cell; and

FIGS. 36A to 36F are sectional views showing, in sequence, a method for producing a wiring structure of the fuel cell shown in FIG. 35.

### BEST MODE FOR CARRYING OUT THE INVENTION

Preferred embodiments of the invention will be hereinafter explained with reference to the accompanying drawings. However, the invention should not be restricted to the following embodiments.

The gist of the invention resides in a wiring structure having connection wiring for electrically connecting elements with one another or one element with another constituent element. Here, the term “element” represents those active elements such as semiconductor elements (for example, IC chips, VLSI chips, etc), passive elements such as capacitors and resistors, and other elements, and therefore it should not be limited to specific elements. These elements may be used solely or in combination of two or more elements. Further, the term “constituent elements” represents arbitrary layers, films, components, and so forth, that are essentially necessary or are used whenever desired, for producing the wiring structure. For example, it represents circuit components such as wiring layers and electrodes, and external connection terminals. The connection wiring can be formed in a desired pattern on a base such as an insulating substrate and an insulating film. The connection wiring generally includes those such as plane-wise extended wirings, three-dimensionally extended wirings, and wirings that penetrate through insulating films. The wiring structure of the invention may have individually these connection wirings or in an arbitrary combination of two or more kinds of connection wirings. If necessary, the prior art connection wiring may be used in combination with the connection wiring of the invention.

The wiring structure of the invention can be used in various technical fields. Particularly, because the wiring structure of the invention can easily provide a fine and high-density connection wiring without problems such as disconnection, it can be used advantageously for the production of compact and high-performance semiconductor devices, multi-layered wiring substrates and other electronic devices.

In the wiring structure according to the invention, the connection wiring can be produced by the steps of depositing a paste of electrically conductive fine particles, that is prepared by dispersing fine conductive particles having a particle diameter of 100 nm or below in a dispersant, on an electrically insulating base in accordance with a predetermined wiring pattern, and then sintering a wiring precursor so formed. Here, the term “base” represents arbitrary constituent elements on which the connection wires are formed, and its examples include an insulating layer, an insulating film, an interlayer insulating film and other electrically insulating elements that have already been formed. The examples of the base further include silicon substrates and other semiconductor substrates and circuit substrates. If necessary, semiconductor elements and other elements can also be used as the base.

The paste of the electrically conductive fine particle can be prepared by using electrically conductive fine particles, a dispersant and arbitrary additives that are used whenever necessary, as the starting materials and also by using a customary technology such as kneading. Though not particularly limited, the electrically conductive fine particles preferably include conductive metal fine particles from the aspects of easy availability, performance when processed into the connection wiring, and durability. Suitable examples of electrically conductive metals include gold, silver, copper, platinum, nickel, palladium, tin and their oxides and alloys, though they are in no way restrictive. The particle diameter of the fine particles of the conductive metal is generally at a nanometer scale (the particle diameter of about 100 nm or below), preferably about 50 nm or below, more preferably about 20 nm or below and most preferably within the range of about 2 to 10 nm. When the size of the fine particles of the conductive metal is reduced down to the nanometer scale, sintering can be carried out at a temperature far lower than the original melting point of the metal and thus the intended connection wire can be easily produced. When nickel particles having a particle diameter of about 10 nm are used as the conductive particles, for example, the nickel particles aggregate and are integrated when heated to about 100 to 200° C. Therefore, upon heating and sintering, the electric conductor can be easily obtained, and thus, since the resulting conductor is homogeneous, a wiring pattern having a low electric resistance and excellent electric characteristics can be formed.

It can be stated that a paste of the silver nanometer-sized particles is an example of the useful conductive fine particle paste.

The silver particles used herein are silver particles having a particle diameter of about 3 to 7 nm. The silver particles are dissolved in a dispersant such as tetradecane to obtain a paste having a viscosity of about 10 to 70 mP·s. The solid content of this paste is about 40 to 60 wt %. Using this paste, a fine pattern (line width: about 10 nm) can be formed on the base such as glass, a polyimide resin, copper, nickel, etc, with an ink jet printer. When the pattern is sintered at about 250° C. for one hour, a connection wire having a silver content of about 95 to 98% after hardening can be obtained.

Further, the conductive fine particle paste prepared using the nano-sized fine particles can be formed into a liquid form that is far more homogenous than that obtained using the prior art conductive paste. Consequently, this conductive paste can fill fine holes that cannot be filled with the prior art conductive paste. Moreover, when the wiring pattern is formed, an extremely fine pattern can be formed. In addition, printing by using the ink jet system that has not been attempted using the prior art conductive paste becomes possible as will be explained later.

The step of depositing the conductive fine particle paste onto the base can be carried out preferably by the printing method. When the conductive paste is deposited by the printing method, the connection wiring can be formed into an arbitrary pattern. The conductive pattern can easily form not only planar connection wiring but also three-dimensionally extended cubic connection wiring. When the connection wiring is three-dimensionally formed by using this conductive paste, the wiring patterns can be electrically connected among the layers when forming the wiring patterns in multiple layers without forming via-holes as have been necessary in the prior art. Note in this specification that the term “connection wiring” is specifically used in the sense that the wiring pattern can be formed within the plane and at the same time interlayer electric connection can be formed between the layers.

The printing method useful for forming the connection wire from the conductive fine particle paste includes a printing method by the ink jet system and a distribution printing method using supplying means such as a dispenser, though these methods are not particular restrictive. When the dispenser or the like is employed, the connection wiring may be formed by three-dimensionally moving an application side of the conductive paste or moving three-dimensionally a target product to which the paste is applied, while the dispenser is supported by an X-Y table, for example.

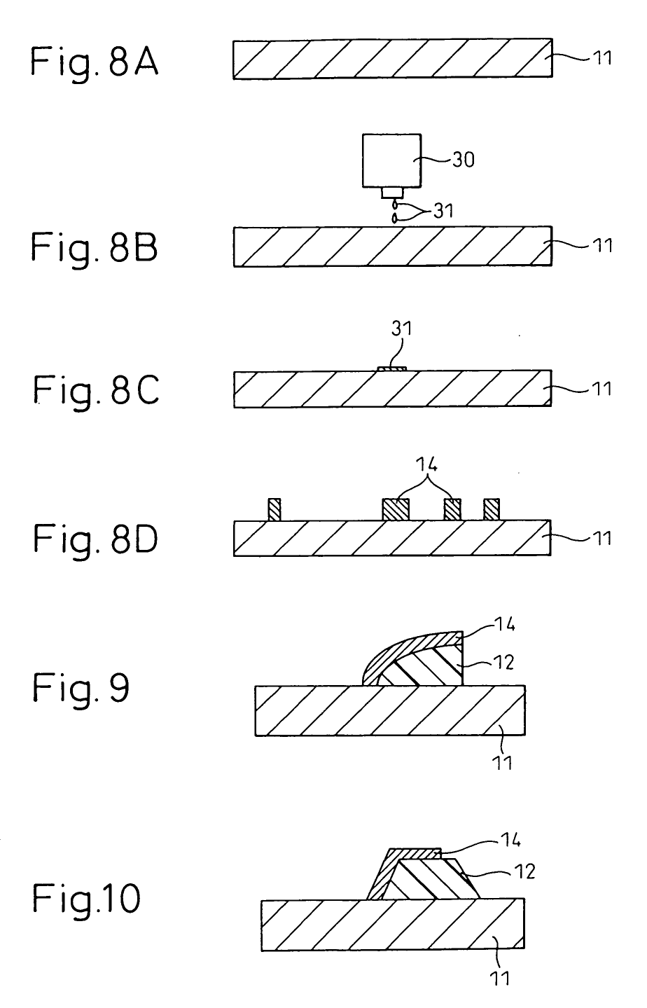

FIGS. 8A to 8D show, in sequence, a method for forming the connection wiring of the invention by the ink jet printing system. Though the drawings show the base and the ink jet printer in a simplified form, they are actually much more complicated in construction.

First, as shown in FIG. 8A, a base (here, a silicon substrate) 11 is prepared. The silicon substrate 11 is used after being rinsed and cleaned by washing with a solvent. To improve adhesion of the conductive fine particle paste, a paste affinity treatment may be applied to the substrate surface in accordance with a desired wiring pattern. Laser irradiation, for example, is effective for this paste affinity treatment.

Next, as shown in FIG. 8B, the conductive fine particle paste 31 is injected from the ink jet printer 30 towards a wiring pattern formation region of the silicon substrate 11. The conductive paste 31 is thinly deposited as shown in FIG. 8C. Injection of the paste is generally carried out a plurality of times because a sufficient film thickness cannot be acquired by a single injection of the paste in the ink jet system.

After ink jet printing is completed, the resulting thin film is further sintered, and the wiring pattern (connection wiring) 14 having a predetermined film thickness can be exactly formed in the desired region as shown in FIG. 8D.

When the conductive paste is printed by the ink jet system, small droplets of paste generally overlap with one another to form the thin film. However, when the viscosity is adjusted, the conductive paste can be deposited in the form of fine tablets (small discs or other fine articles). Means for forming the tablets includes the ink jet printer and the dispenser.

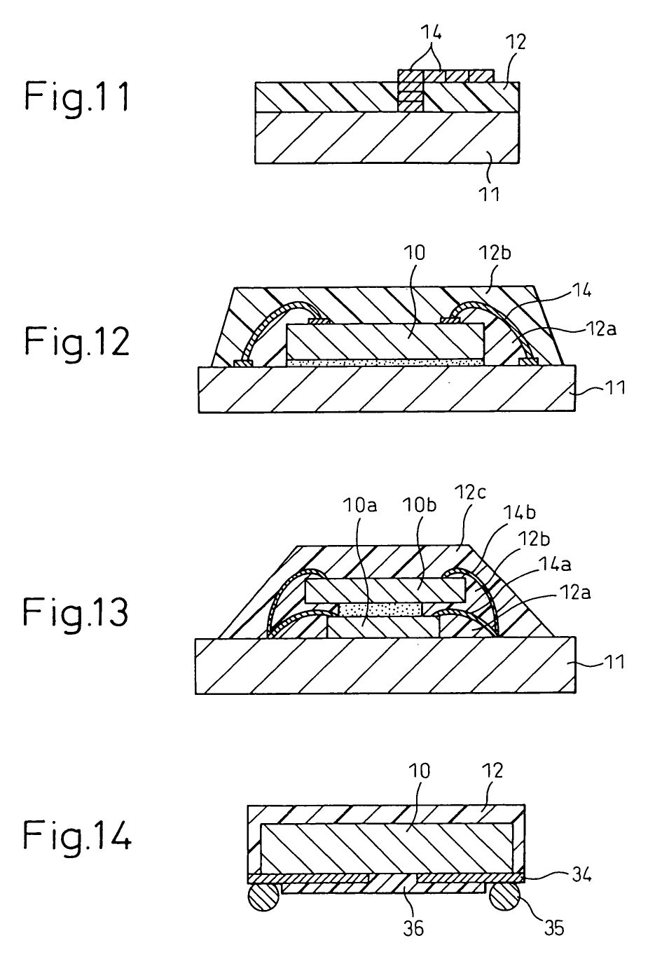

Further, when the connection wiring is formed by repeatedly depositing the conductive fine particle paste in the form of the fine tablets on the base, the insulating films and the like that are to be formed adjacent to the connection wires may be formed by the steps of forming an insulating film 12 on the substrate 11, opening fine pores at predetermined positions of the insulating film 12 by conventional methods such as etching, and filling a necessary number of conductive tablets 14, as will be explained later with reference to FIG. 11. Alternatively, the insulating film and the fine pores may be formed simultaneously through deposition of tablets of a material having electrically insulating property in the same way as the formation of the connection wires.

In another aspect of the invention, the connection wiring can be advantageously formed by using a cell-like support having a three-dimensional structure as the base and applying the conductive fine particle paste to the surface of the support by coating, deposition, packing or other methods. The material used for forming the cell-like support is preferably an electrically insulating material. Suitable examples of the insulating material include an epoxy resin and a polyimide resin. Incidentally, the cell-like support may be used either individually or in combination of two or more supports. When a plurality of cell-like supports is used, the supports may be either juxtaposed or stacked one upon another to an arbitrary height.

The cell-like support may be used in various forms or configurations. For example, the cell-like support may have an arbitrary form necessary for forming a desired wiring pattern. In the practice of the invention, the method based on the use of the cell-like support in such a form is particularly called a “free cell method”.

FIG. 9 is a sectional view showing schematically a method of forming a connection wiring by using the free cell method. In the illustrated method, a free cell 12 is formed on an electrode terminal formation surface of a semiconductor substrate 11, and the conductive fine particle paste is applied to a portion ranging from the electrode terminal formation surface of the semiconductor substrate 11 to the surface of the free cell 12 and is then sintered to form the connection wire 14. Materials suitable for forming the free cell 12 are those which have an electrically insulating property such as a resin paste and can be applied and formed into an arbitrary shape by using a dispenser or the like. Because this method forms the free cell 12 into an arbitrary shape and forms the connection wire, it is not limited in the shape of the cell and its size.

Further, the cell-like support may have a predetermined basic form. It is particularly preferred that a base necessary for forming a desired wiring pattern by combining two or more cell-like supports having the same basic form is given. In the invention, the method based on the use of the cell-like support or supports having such a basic form is particularly called a “basic cell method”.

FIG. 10 is a sectional view schematically showing a method of forming the connection wiring by using the basic cell method. In the illustrated example, a basic cell 12 having a truncated pyramidal shape is used. The shape of the basic cell is not limited to the form shown in the drawing, and it may be a prism, a cylinder or a sphere. The conductive fine particle paste is applied to a portion ranging from the electrode terminal formation surface of the semiconductor substrate 11 to the surface of the basic cell 12 and is then sintered to form the connection wiring 14.

In the practice of the invention, two or more basic cells are generally used in combination in accordance with the form of the desired wiring pattern. In this way, a three-dimensionally extended cubic connection wiring can be formed by using the conductive fine particle paste. The basic cell is generally formed by using an ordinary material having the electric insulating property in the same way as the free cell explained with reference to FIG. 9. In the basic cell method, on the other hand, a plurality of basic cells is integrated to form the wiring layer or the wiring substrate. Depending on design, therefore, it is possible to use in combination a basic cell formed of a dielectric material for adjusting a capacitance, a basic cell formed of a material for adjusting a heat transfer coefficient, a basic cell formed of a material for adjusting a heat expansion coefficient, and the like.

As modified examples of the free cell method and the basic cell method, the connection wiring can be produced by the steps of forming tablets, that is, miniaturized cells in a very small size (micro cells; conductive micro cells) from a conductive material, preferably from a conductive fine particle paste, and depositing or filling a necessary number of such micro cells in accordance with the design of the wiring pattern. In the invention, the method based on the use of the conductive micro cells for forming the connection wire is specifically called a “micro cell method”.

FIG. 11 is a sectional view schematically showing a method of forming the connection wiring by the micro cell method. In the illustrated method, after an insulating film 12 is first formed on a semiconductor substrate 11, fine pores are defined by the method such as etching. Next, the conductive tablets 14 are serially added to close the fine pores and are further deposited onto the insulating film, too. The conductive tablets 14 may be formed by, for example, causing the conductive paste to fly to the substrate 11 in accordance with the ink jet system. Alternatively, the conductive tablets 14 may be formed by using a method that jets the conductive paste from the dispenser onto the substrate 11. The connection wiring can be completed when the conductive tablets are successively sintered at a predetermined temperature.

The method for forming the insulating film 12 on the substrate 11 was explained in the example shown in FIG. 11. It is recommended in the invention to deposit tablets of an electrically insulating material onto the insulating film 12, too, in place of the method described above. Alternatively, the portion of the insulating film 12 may be formed by use of the free cells or the basic cells described above.

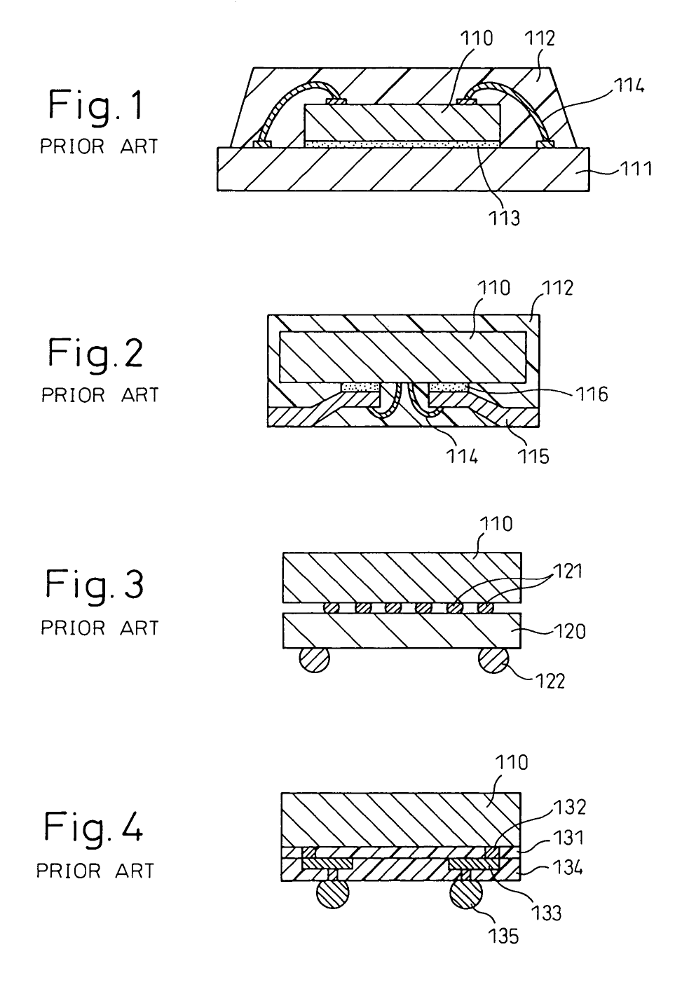

FIGS. 12 to 18 are each a sectional view schematically showing a semiconductor package or multi-layered wiring substrate incorporating the wiring structure of the invention. Because these sectional views correspond to the semiconductor package and to the multi-layered wiring substrate explained with reference to FIGS. 1 to 7, reference should be also made to these drawings.

FIG. 12 is a sectional view of a semiconductor package of the invention produced without using the wire bonding method. In the illustrated semiconductor package, too, the semiconductor element (for example, LSI chip) 10 is mounted onto the wiring substrate 11 through the die bonding paste or the die bonding film in the same way as in the semiconductor package shown in FIG. 1. The semiconductor element 10 and the wiring substrate 11 are connected to each other through the connection wiring 14. The connection wiring 14 is formed by forming the free cell 12a according to the invention, applying the conductive fine particle paste on the free cell 12a and then conducting baking without using the bonding wire used in the method shown in FIG. 1. The semiconductor element 10 and the connection wiring 14 are sealed with the insulating resin 12b such as the epoxy resin. The semiconductor package can thus be fabricated into a smaller size than the semiconductor package shown in FIG. 1 and moreover without any drawback such as disconnection of the bonding wiring.

FIG. 13 is also a sectional view of the semiconductor package of the invention produced without using the wire bonding method. In the illustrated the semiconductor package, a first semiconductor element 10a and a second semiconductor element 10b are stacked on the semiconductor substrate. In the first semiconductor element 10a, the connection wiring 14a can be formed by the steps of forming the free cell 12a according to the invention, then applying the conductive fine particle paste on the free cell 12a and conducting sintering in the same way as in FIG. 12. In the case of the second semiconductor element 10b, too, the connection wiring 14b can be formed by the steps of forming the free cell 12b according to the invention, then applying the conductive fine particle paste on the free cell 12b and conducting sintering. The semiconductor elements 10a and 10b and the connection wirings 14a and 14b are sealed with the insulating resin 12c such as the epoxy resin.

FIG. 14 is a sectional view of a semiconductor package produced by assembling the wiring structure of the invention as a package that can replace the lead frame package shown in FIG. 2. In the case of the package shown in the drawing, the connection wiring 34 of the invention is formed by the method such as the printing method using the conductive fine particle paste in place of the lead terminals and is further sealed with the insulating resin 36. The back and side surfaces of the semiconductor element 10 are sealed with the insulating resin 12. Solder bumps 35 are disposed as external connection terminals. In comparison with the lead frame package shown in FIG. 2, the semiconductor package shown in FIG. 14 is finished extremely compactly.

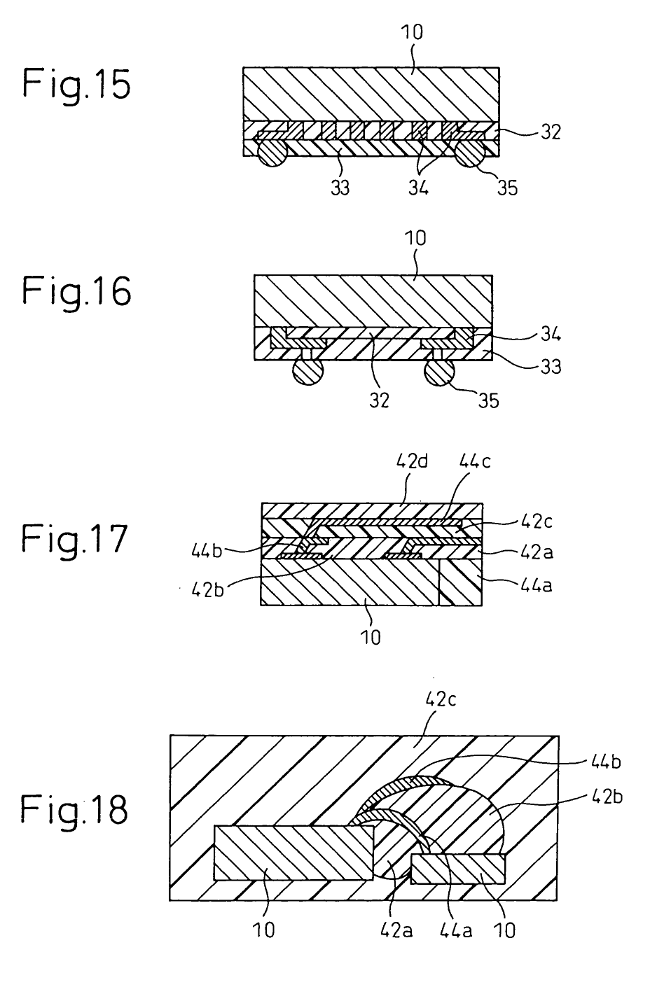

FIG. 15 is a sectional view of the semiconductor package of the invention produced without using the flip chip method. In the semiconductor package shown in the drawing, the insulating film 32 originating from the free cell is formed from an insulating cell material in place of the flip chip method, and the connection wiring 34 is formed from the conductive fine particle paste. The insulating film 32 and the connection wiring 34 are sealed with the insulating resin 33, and bumps 35 as external connection terminals are further fitted to the connection wiring 32. Because the illustrated semiconductor package does not use the flip chip, it can accomplish the reduction of the size and the thickness and can be easily produced.

FIG. 16 is a sectional view of the semiconductor package having the rerouted wiring connections applied according to the invention. In the semiconductor package shown in the drawing, the insulating film 32 originating from the free cell is formed from the insulating cell material by omitting the complicated process steps of the formation of the insulating film, the formation of the via-holes, filling of the solder into the via-holes and plating and patterning of rerouted wiring, and the connection wiring (rerouted wiring pattern) 34 is formed of the conductive fine particle paste. The insulating film 32 and the connection wiring 34 are sealed with the insulating resin 33, and the solder bumps 35 as the external connection terminals are fitted to the connection wire 32. In contrast with the semiconductor package shown in FIG. 4, the semiconductor package shown in FIG. 16 can form the desired rerouted wiring connection more easily and moreover, more thinly.

FIG. 17 is a sectional view of a multi-layered wiring substrate produced by using the build-up method according to the invention. The illustrated multi-layered wiring substrate can be produced by the steps of forming the wiring pattern on the surface of the semiconductor element (for example, a system LSI), forming the insulating film 42a originating from the free cell from the insulating cell material, and forming the connection wiring 44a from the conductive fine particle paste. Thereafter, the insulating film 42b originating from the free cell is formed from the insulating cell material and the connection wiring 44b is formed from the conductive fine particle paste. Successively, the insulating film 42c originating from the free cell is formed from the insulating cell material, and the connection wiring 44c is formed from the conductive fine particle paste. Finally, the connection wiring 44c is sealed with the insulating resin 42d.

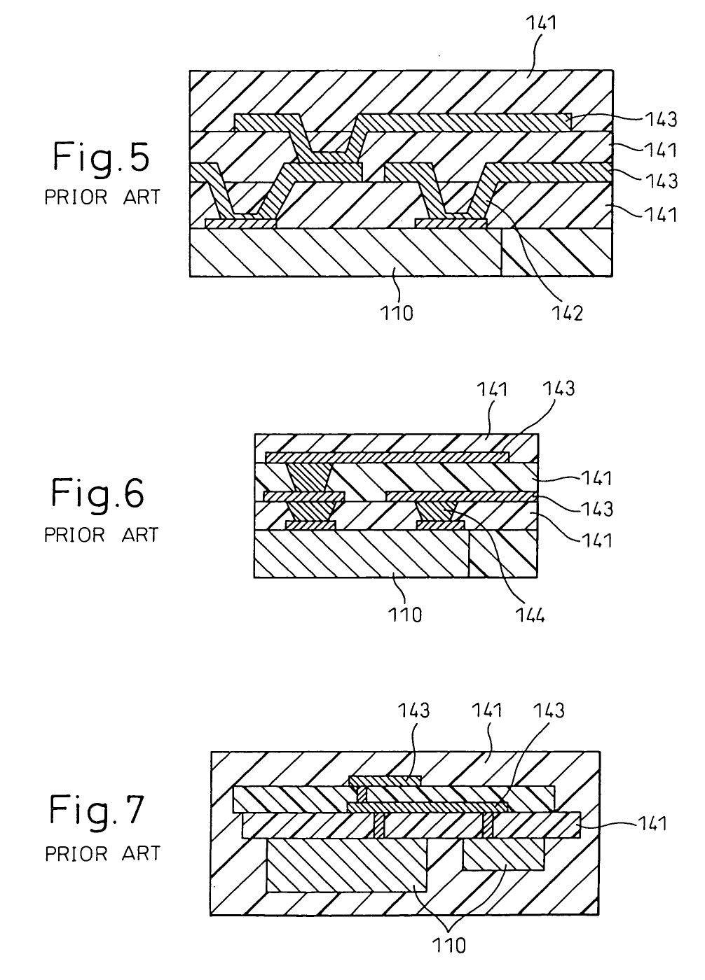

In the illustrated multi-layered wiring substrate, a via shape of about 5×10 μm and a pitch of about 50 μm can be obtained by the application of the conductive fine particle paste. Further, because the thickness of the insulating film originating from the free cell is about 10 μm, the wiring pattern can be formed with an extremely fine line-and-space of about 10/10 μm. It can be understood, from a comparison of the multi-layered wiring substrate shown in FIG. 17 with the multi-layered wiring substrates shown in FIGS. 5 and 6, that the invention enables to produce the wiring substrate in a smaller and compacter size and with a higher wiring density.

FIG. 18 is a sectional view of the semiconductor package produced by the embedding mount technology (EMT) according to the invention. The illustrated semiconductor package is produced by disposing two semiconductor elements 10 having different sizes at the same surface level, arranging them at predetermined positions, forming the insulating film 42 originating from the free cell from the insulating cell material and forming the connection wiring 44a from the conductive fine particle paste. The insulating film 42b originating from the free cell is thereafter formed from the insulating cell material and the connection wiring 44b is formed from the conductive fine particle paste. The package is successively sealed as a whole with the insulating resin 42c. In the illustrated semiconductor package, a smaller EMT package can be produced more easily at a higher yield.

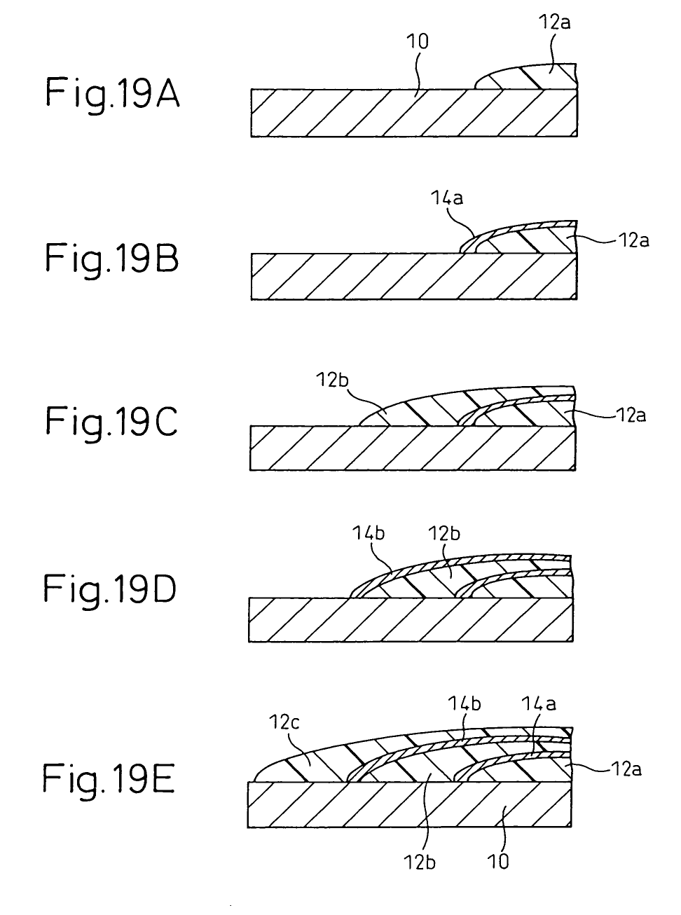

FIGS. 19A to 19E are sectional views showing a method for forming the connection wiring of the invention in accordance with the free cell method.

First, as shown in FIG. 19A, the cell material is applied to the electrode terminal formation surface of the semiconductor element 10 through the dispenser to form a first layer cell 12a. Next, as shown in FIG. 19B, a first layer connection wiring 14a is formed on the surface of the cell 12a by use of the conductive fine particle paste. The connection wiring 14a is formed in such a manner as to be electrically connected to the electrode terminal of the semiconductor element 10. When the cell 12a is formed, therefore, the end portion of the cell 12a is positioned to the electrode terminal formed on the electrode terminal formation surface. The connection wiring 14a can be formed from the conductive paste by printing the paste into a desired pattern in accordance with the ink jet printing system, for example. Masking means that is required in a screen-printing method is not necessary.

In the method shown in the drawing, the sectional shape of the cell 12a is lower at its edge connected to the electrode terminal as shown in FIG. 19A. For this reason, the conductive fine particle paste can be applied cubically (three-dimensionally) onto the surface of the cell 12a to form the connection wiring 14a by the printing method.

As the method for forming the cell 12a and the connection wiring 14a, it is also possible to employ a method involving the steps of heating and curing the cell material applied to the electrode terminal formation surface, applying then the conductive paste to the surface of the cell 12a, and heating and sintering the conductive paste to form the connections wiring 14a. It is further possible to employ a method involving the steps of forming the cell 12a by use of a cell material having a predetermined shape retaining property, applying the conductive paste to the surface of the cell 12a, and heating the cell 12a and the conductive paste so that curing of the cell 12a and sintering of the conductive fine particle paste can be simultaneously achieved.

Successively, the cell material is applied in such a manner as to cover the cell 12a and the connection wiring 14a previously formed to form a second layer cell 12b covering the first layer cell 12a and the connection wiring 14a as shown in FIG. 19C.

Thereafter, a second layer connection wiring 14b is formed on the surface of the cell 12b by using the conductive paste as shown in FIG. 19D. The cell 12b and the connection wiring 14b can be formed in the same way as described above.

Finally, as shown in FIG. 19E, the cell material is applied in such a manner as to cover the cell 12b, the connection wiring 14b and the electrode terminal formation surface of the semiconductor element 10 to form a third layer cell 12c. A large number of electrode terminals are arranged on the electrode terminal formation surface of the semiconductor element 10. When the formation method of the connection wiring using the cell and the conductive fine particle paste is utilized, the connection wirings electrically connected to all the electrode terminals can be formed.

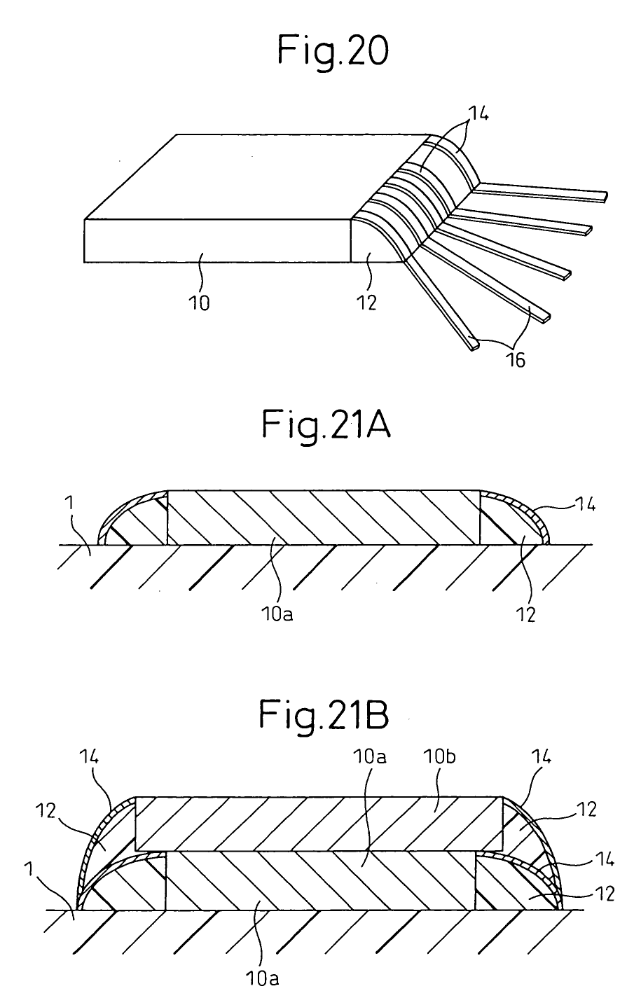

FIG. 20 shows an example of the semiconductor package electrically connected to both of the semiconductor element and the wiring pattern formed on the wiring substrate by the free cell method.

In the illustrated semiconductor package, the insulating cell material is applied in such a manner as to bury a step portion (corresponding to the height of the semiconductor element 10) defined between the side surface of the semiconductor element 10 and the surface of the wiring substrate as the base of the semiconductor element 10, and the cell 12 as the support of the connection wiring 14 is formed between the electrode terminal formation surface of the semiconductor element 10 and the surface of the wiring substrate. Next, the connection wiring 14 for electrically connecting the electrode terminal of the semiconductor element 10 and the wiring pattern 16 formed on the surface of the wiring substrate is formed on the surface of the cell 12.

When the printing method using the conductive fine particle paste is used in this method for forming the connection wiring 14, the connection wiring can be easily formed cubically (three-dimensionally) as described above. When the connection wiring 14 is formed on the surface of the cell 12 as shown in the drawing, the semiconductor element 10 can be mounted to the wiring substrate while the semiconductor element 10 and the wiring pattern 16 are electrically connected to each other.

The wire bonding method or the like has been used in the past as the method for connecting the semiconductor element 10 to the wiring pattern of the wiring substrate. However, when the cell 12 and the conductive paste are used as in this embodiment, the semiconductor element 10 and the wiring pattern 16 can be connected easily and electrically to each other. Particularly when the conductive fine particle paste is used, even an extremely high-density wiring can be easily formed.

FIGS. 21A and 21B show, in sequence, a method for stacking and mounting the semiconductor elements by utilizing the method for forming the free cell on the side surface of each semiconductor element and forming the connection wiring of the conductive fine particle paste on the outer surface of the free cell.

In the illustrated semiconductor device, the cell 12 is formed on the side surface of the semiconductor element 10a of a first stage while the semiconductor element 10a is supported on the support 1 such as the wiring substrate as shown in FIG. 21A. The connection wiring 14 is further formed on the outer surface of the cell 12 by using the conductive fine particle paste. Next, as shown in FIG. 21B, the semiconductor element 10b of a second stage is stacked on the first stage semiconductor element 10a, the cell 12 is formed on the side surface of the second stage semiconductor element 10b, and the connection wiring 14 is further formed on the outer surface of the cell 12 of the second stage. The second stage cell 12 can be formed by applying an insulating cell material in such a manner as to cover the cell 12 of the lower stage and the connection wiring 14. The method of forming the connection wiring 14 on the second stage cell 12 can be advantageously carried out by the printing method using the conductive fine particle paste.

In the illustrated semiconductor device, a semiconductor element larger than the first stage semiconductor element 10a is mounted as the second stage semiconductor element 10b. However, the semiconductor element 10b of the upper stage need not always be greater than the semiconductor element 10a of the lower stage. Further, although the drawings show an example where the semiconductor elements are stacked in two stages, the semiconductor elements may be stacked in a greater number of stages. Furthermore, although the semiconductor elements 10a and 10b shown are stacked on the support such as the wiring substrate, the support is not limited to the wiring substrate and it may be any support. For example, a casing of the device may be utilized as the support.

In the prior art semiconductor devices, it has been customary to electrically connect each semiconductor element and the wiring pattern by the wiring bonding method when a plurality of semiconductor elements are stacked one upon another and are mounted to the wiring substrate or the like. Contrary to this, when the formation method of the connection wiring according to the invention is utilized, the semiconductor elements and the wiring pattern can be electrically connected to one another without using the wire bonding method.

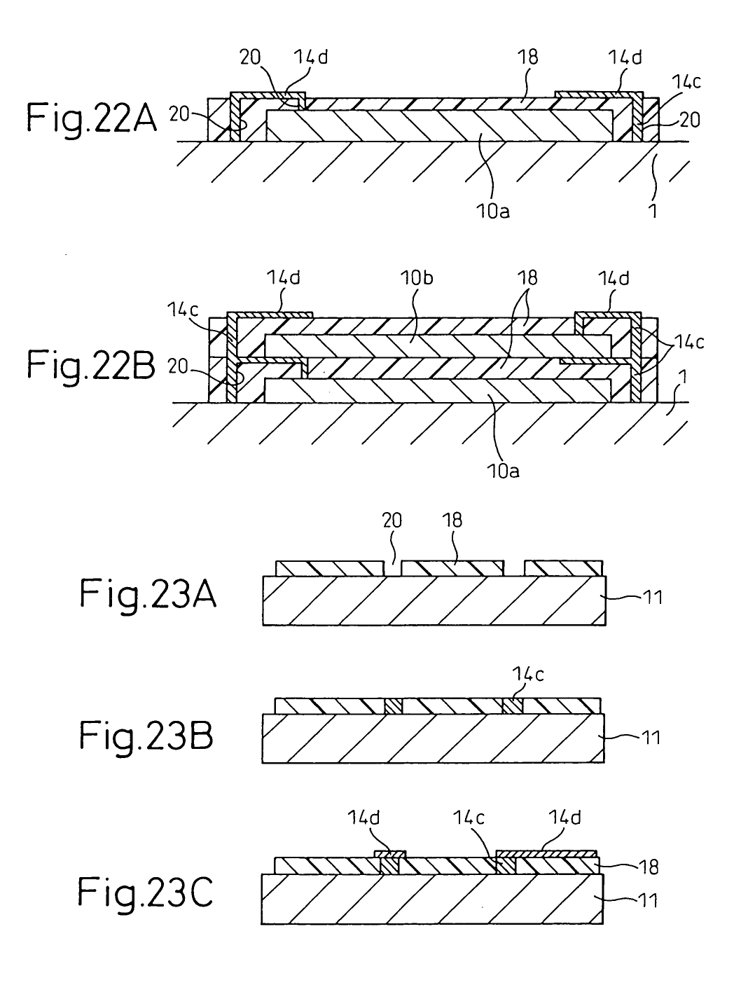

FIGS. 22A and 22B show, in sequence, another embodiment in which the connection wiring is formed by the method similar to the free cell method described above.

In the illustrated semiconductor device, the side surface of the first stage semiconductor element 10a supported by the support 1 such as the wiring substrate and the electrode terminal formation surface are covered with a material having electric insulating property, like the cell material, to form an insulating film 18, and a wiring pattern 14d is then formed. In this embodiment, connection holes 20 penetrating through the insulating film 18 in a direction of the film thickness are formed to electrically connect the wiring patterns among the stages. The conductive fine particle paste is filled into the connection holes 20 to form conduction portions 14c. As the conductive paste has high fluidity, it can easily fill the connection holes 20 even when the conduction holes 20 have an extremely small diameter, and thus the conduction portions 14c can be easily formed.

Next, as shown in FIG. 22B, the second stage semiconductor element 10b is mounted. The side surface of the second stage semiconductor element 10b and the electrode terminal formation surface are covered with the insulating film 18 to form the wiring pattern 14d of the second stage. Incidentally, the wiring pattern 14d to be formed on the surface of the insulating film 18 covering the electrode terminal formation surfaces of the semiconductor elements 10a and 10b can be easily formed into a fine pattern by a printing method utilizing the conductive paste.

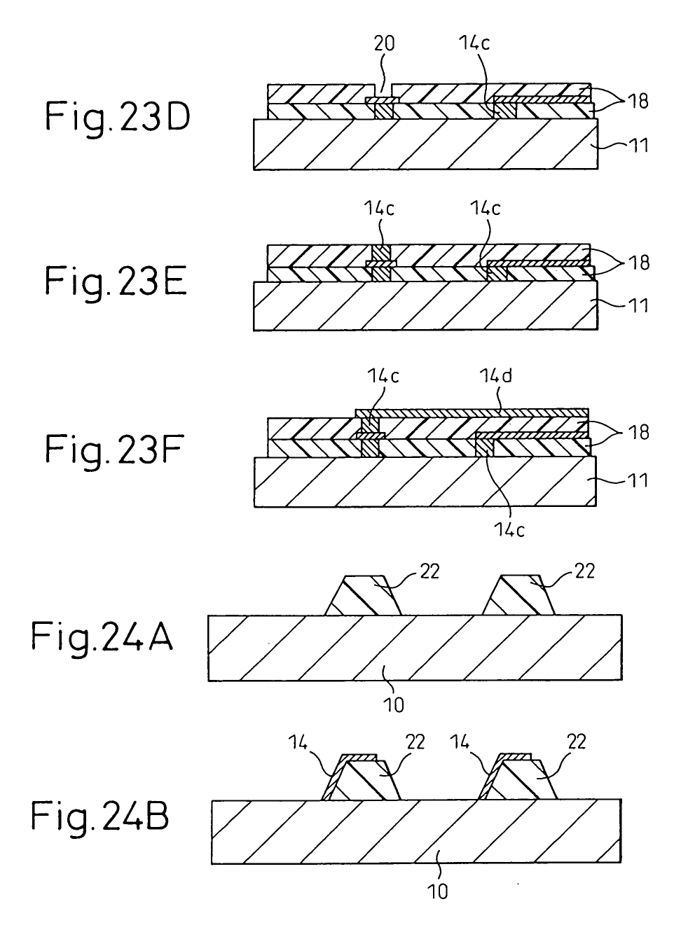

FIGS. 23A to 23F illustrate, in sequence, a method for stacking the wiring patterns on the surface of the substrate 11 by the print-up method using the conductive fine particle paste.

In the illustrated formation method of the multi-layered wiring substrate, the insulating film 18 is first formed on the surface of the substrate 11 as shown in FIG. 23A and is then etched to form connection holes 20 for establishing electric conduction among the wiring patterns between the adjacent layers. Next, as shown in FIG. 23B, the conductive fine particle paste is filled into the connection holes 20 to form conduction portions 14c. The wiring pattern 14d is thereafter formed on the surface of the insulating film 18 by using the conductive fine particle paste as shown in FIG. 23C. To form the wiring pattern of the next layer, the insulating film 18 of the second layer is disposed in such a manner as to cover the insulating layer of the first layer as shown in FIG. 23D. The connection holes 20 are defined in required portions of this insulating film 18. Next, as shown in FIG. 23E, the conductive fine particle paste is filled into the connection holes 20 defined in the insulating film 18 to form the conduction portions 14c. Finally, as shown in FIG. 23F, the wiring pattern 14d is formed on the surface of the insulating film 18 of the second layer by using the conductive fine particle paste.

In such a formation method of the multi-layered wiring substrate, the use of the conductive fine particle paste makes it possible to acquire a multi-layered wiring substrate in which the wiring patterns 14d are electrically connected through the conduction portions 14c. The use of the conductive fine particle paste makes it also possible to acquire a wiring substrate in which wirings are far finer than those of the multi-layered wiring substrate according to the prior art.

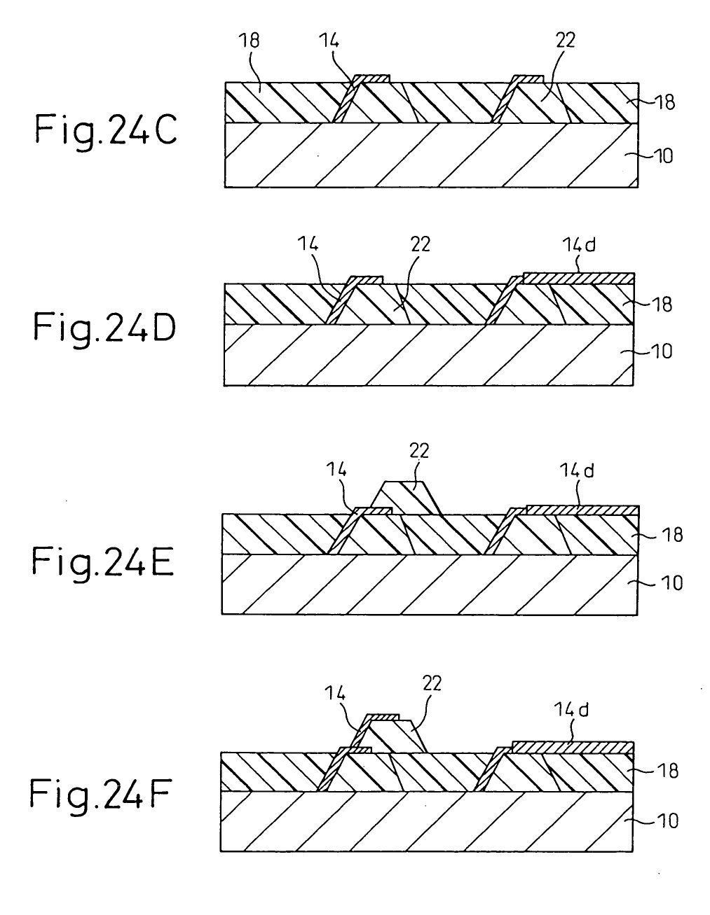

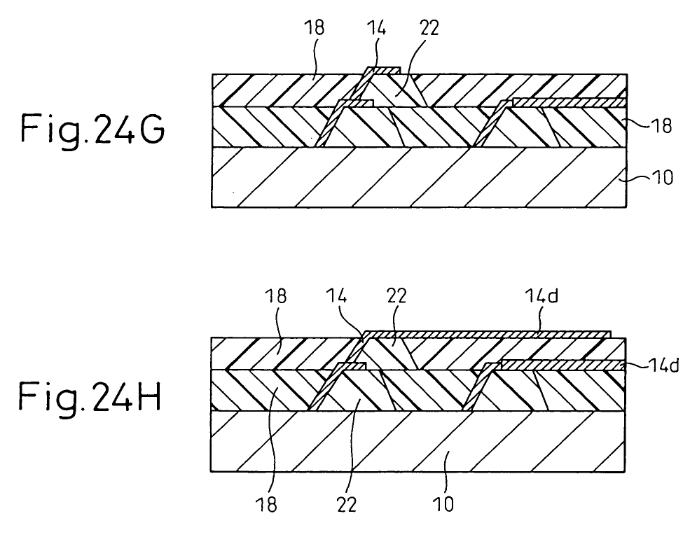

FIGS. 24A to 24H are sectional views showing a method for forming the connection wiring of the invention in accordance with a basic cell method, by using the basic cell and the conductive fine particle paste to complete the semiconductor device. The basic cell is used in order to produce cubic (three-dimensional) wiring using the conductive fine particle paste. The basic cell can be formed of ordinary materials having the electric insulating property in the same way as the free cell described above. Because the basic cell method basically forms the wiring layer, wiring substrates and the like by integrating a plurality of basic cells, it is possible, depending on the design of the intended product, to combine basic cells, made of a dielectric material, for adjusting the capacitance and the like, basic cells made of a material for adjusting a heat transfer coefficient, basic cells made of a material for adjusting a thermal expansion coefficient, and so forth.

In the illustrated formation method of the semiconductor device, the basic cell 22 is first formed on the electrode terminal formation surface of the semiconductor element 10 as shown in FIG. 24A. The basic cell 22 is shaped into a trapezoidal sectional shape. In the subsequent step, the connection wiring can be easily formed by the printing method using the conductive fine particle paste in such a manner as to extend from the side surface to the upper surface.

Next, as shown in FIG. 24B, the connection wiring 14 is formed by using the conductive fine particle paste in such a manner as to extend from the electrode terminal formation surface of the semiconductor element 10 to the side surface of the basic cell 22 and its upper surface. According to the printing method using the conductive fine particle paste, the cubic (three-dimensional) connection wirings 14 can be formed at one time, and via-holes and the like for electrically connecting the inter-layer wiring patterns need not be formed.

Next, as shown in FIG. 24C, the insulating film 18 is formed at the substantially same thickness as the basic cell 22 to form a first layer insulating layer. After the insulating film 18 is formed, a wiring pattern 14d is formed on the surface of the insulating film 18 by using the conductive fine particle paste as shown in FIG. 24D.

Thereafter, to form the wiring pattern of the next layer, the basic cell 22 is formed on the surface of the insulating film 18 as shown in FIG. 24E. The connection wiring 14 is then formed by using the conductive fine particle paste in such a manner as to extend on the side surface of the basic cell 22 so formed and on its upper surface as shown in FIG. 24F. Each basic cell 22 is arranged and positioned to the position at which the wiring patterns 14 are to be electrically connected between the layers.

Subsequently, the second layer insulating film 18 is formed in the same way as described above as shown in FIG. 24G, and the wiring pattern 14d is formed on the surface of the insulating film 18 in the same way as described above as shown in FIG. 24H.

As described above, according to the method in which the connection wiring 14 is formed by using the basic cell 22 and the conductive fine particle paste, it becomes possible to easily and compactly produce a semiconductor device in which the wiring patterns 14d are electrically connected between the layers through the connection wiring 14 formed in the basic cell 22.

According to the method of this embodiment, a required semiconductor device or a package structure can be constituted by use of the basic cells 22 that are formed and standardized to a certain extent, in accordance with the arrangement of the electrode terminals and with the product design.

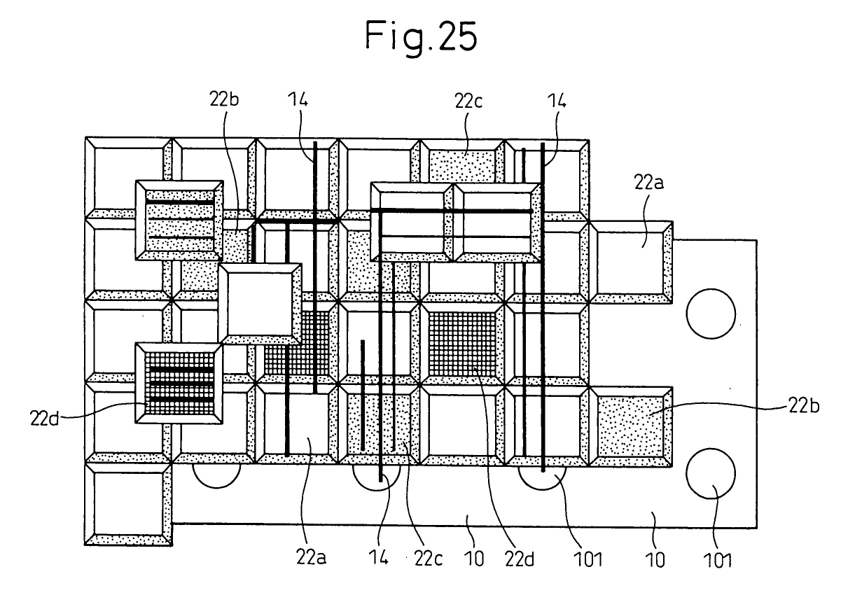

FIG. 25 shows another method for forming the connection wiring on the electrode terminal formation surface of the semiconductor element 10 by using the basic cell 22. The drawing shows a planar arrangement of the basic cells 22 in each layer. Incidentally, in practice, the insulating film 18 is formed in the same layer as the basic cell 22 as shown in FIG. 24H.

As shown in FIG. 25, the basic cell comprises a combination of a basic cell 22a made of an ordinary insulating material, a basic cell 22b for adjusting a thermal expansion coefficient, a basic cell 22c for adjusting a heat transfer coefficient and a basic cell 22d made of a dielectric material, for adjusting a capacitance or the like. Electrode terminals 101 are formed on the electrode terminal formation surface.

It is thus possible, by using different basic cells 22 having various functions in combination, to provide a semiconductor device exhibiting characterizing functions and composite functions in a compact size that have not been accomplished by the prior art technologies. Because the connection wiring 14 is formed from the conductive paste in the illustrated semiconductor device, the connection wiring 14 can be formed into a very fine pattern. Therefore, the connection wiring 14 connected to the electrode terminal 101 can be easily formed as shown in the drawing, and the connection wiring 14 can be formed to an arbitrary pattern inside the electrode terminal formation surface of the semiconductor element 10.

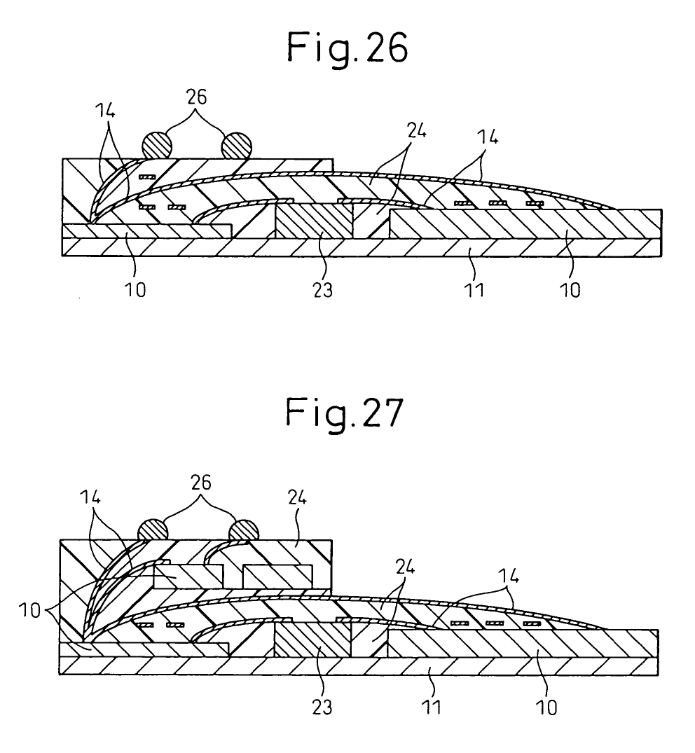

The method described above for forming the connection wiring through the combination of the basic cells 22 and the conductive fine particle paste can be advantageously used for producing a cell integrated module and a cell integrated module board shown in FIGS. 26 to 28.

In the cell integrated module shown in FIGS. 26 and 27, the semiconductor elements 10 and circuit components 23 are electrically connected through a cell integrated body 24 and the connection wirings 14, and are supported on the substrate 11. In the cell integrated body 24, the basic cell 22 and the insulating film 18 constitute the required connection wires 14 as an inner layer. Reference numeral 26 denotes an external connection terminal disposed for mounting. In the formation of the cell integrated module, it is possible to mount, plane-wise, the circuit components on the substrate 11 as shown in FIG. 26 or to arrange the circuit components three-dimensionally as shown in FIG. 27.

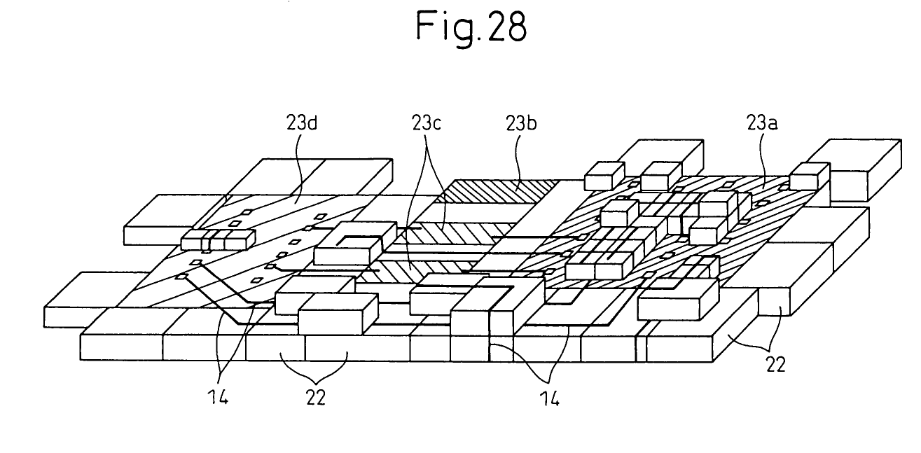

In the cell integrated module board shown in FIG. 28, various basic cells 22 and various circuit components 23a, 23b, 23c and 23d such as the semiconductor elements are combined with one another and are shaped into a board form. As to the basic cells 22, basic cells made of various materials in various sizes are used compositely. When the basic cells 22 and the circuit components 23a to 23d are combined and used in the composite form and the connection wires 14 are formed from the conductive fine particle paste, a cell integrated module board having an arbitrary form can be produced. The fine wires can be arbitrarily formed by using the basic cells 22 and the conductive paste, and a board can be easily obtained by assembling circuit components such as the semiconductor elements in which fine electrode terminals are arranged. When the semiconductor elements are combined with the circuit components, this embodiment can cope with a variety of products.

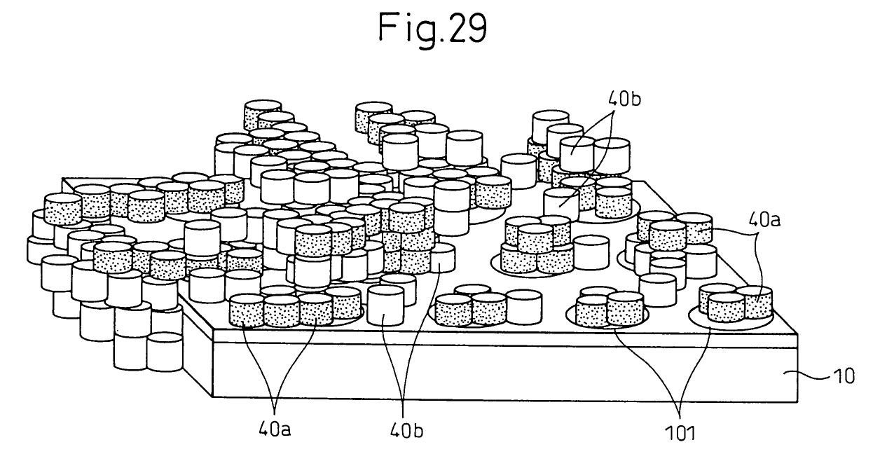

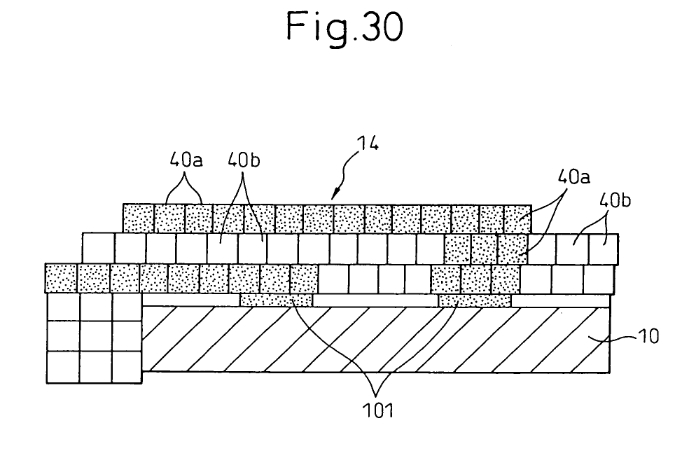

FIGS. 29 and 30 show a method for forming the connection wiring by using micro cells that are finer than the basic cells described above.

FIG. 29 shows the state where the micro cells 40a and 40b are arranged on the electrode terminal formation surface of the semiconductor element 10 to form the connection wirings. Here, the micro cell 40a is a micro cell for wiring having conductivity that is formed into the micro cell shape by using the conductive fine particle paste. The micro cell 40b is an insulating micro cell that is formed into the micro cell shape by using a material having electrically insulating property. The micro cells 40a and 40b can be formed by a method that applies the material into the dot shape (micro cells) by the ink jet system or a dispenser, for example. When the micro cells are arranged and stacked at an arbitrary position inside a plane, an arbitrary cubic arrangement (three-dimensional arrangement) can be obtained. Since the micro cells 40a and 40b can be formed in a size sufficiently smaller than the electrode terminals 101 and the like of the semiconductor element 10 in this embodiment, a plurality of micro cells can be arranged inside the region of the electrode terminal 101.

FIG. 30 shows the state where the connection wiring 14 electrically connected to the electrode terminal 101 of the semiconductor element 10 by three-dimensionally arranging the micro cells 40a and 40b is viewed from the sectional direction. When the micro cell 40a for wiring and the micro cell 40b having the insulating property are combined with each other in this way, the connection wiring can be formed into an arbitrary pattern and as the inner layer.

As shown in the above embodiment, according to the method for forming the connection wiring by utilizing the micro cells 40a and 40b, the wiring can be produced extremely finely and thus can be suitably utilized for the production of the semiconductor devices requiring the fine wiring patterns. The method can also be used effectively as a method of producing a small-sized semiconductor device. Furthermore, because the micro cells 40a and 40b can be arranged in an arbitrary pattern, the connection wiring 14 can be arbitrarily formed, and thus an arbitrary three-dimensional wiring body can be easily formed, too. Consequently, this method for forming the connection wiring can be applied to products for various applications and products having various forms. The method for forming the connection wiring by utilizing the micro cells provides the advantages that heating and sintering of the cells can be easily done and the connection wiring can be formed with a substantially dry system.

The wiring structure of the invention can be also advantageously carried out in other forms.

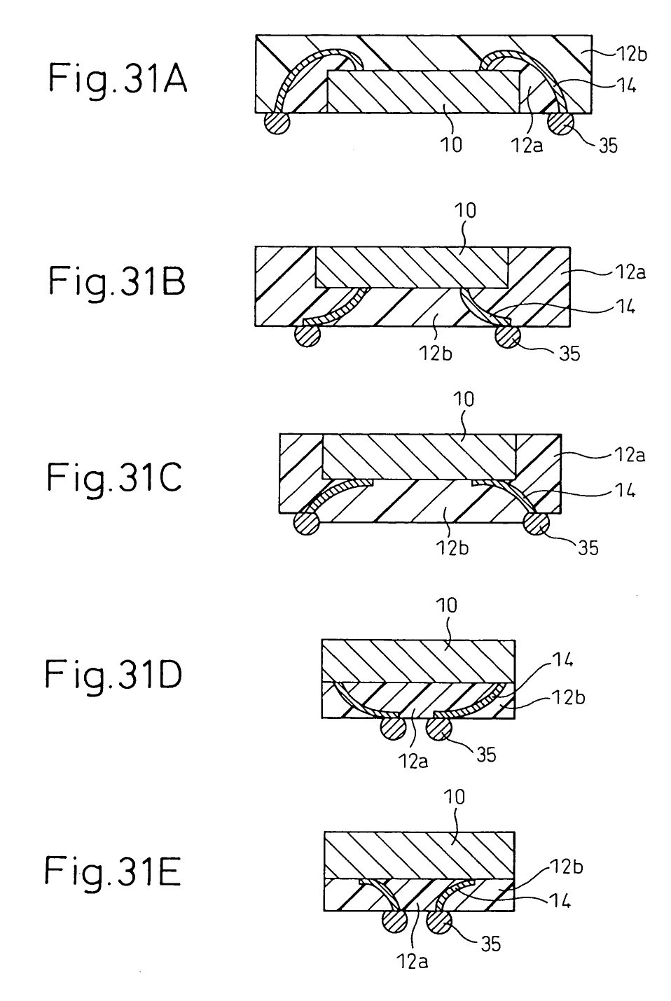

FIGS. 31A to 31E are sectional views each showing a semiconductor package having the wiring structure of the invention assembled therein. These semiconductor packages have a structure analogous to the semiconductor package previously explained with reference to FIG. 12. To reduce the production cost and to expand the utilization range, however, these semiconductor packages are provided in a form not having a substrate. The semiconductor packages shown in the drawings can be easily produced when the fabrication process is carried out on a workbench (not shown) or the like, without using the substrate. Therefore, the semiconductor packages shown in the drawings can be called “eco (economical) packages”.

The semiconductor package shown in FIG. 31A can be produced by forming the free cells 12a on the electrode terminal formation surface of the semiconductor element 10 while the semiconductor element 10 is put on the workbench (not shown). Next, the connection wiring 14 is formed through printing using the conductive fine particle paste to a portion ranging from the side surface of each free cell 12a to the upper surface, and the insulating film 12b is further formed in such a manner as to cover the connection wiring 14. The workbench is thereafter removed and external connection terminals (solder bumps) 35 are fitted to the exposed end surface of the connection wiring 14. The semiconductor packages shown in FIGS. 31B to 31B can be produced in the same way as in FIG. 31A, though the arrangement patterns of the connection wirings and the like are somewhat different. The semiconductor packages can be adjusted to desired sizes through the change of the arrangement patterns.

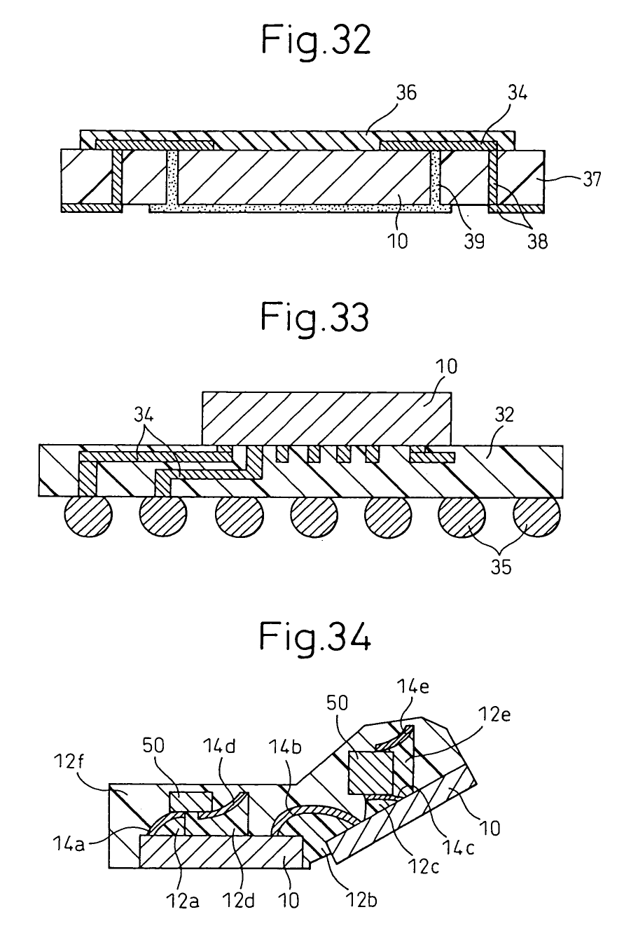

FIG. 32 is a sectional view of a semiconductor package produced, as the one that can replace the prior art lead frame mold package, by assembling the wiring structure of the invention. To reduce the thickness and the size of the package, the semiconductor element 10 is contained in an opened portion of the wiring substrate 37 having the wiring pattern 38, and a gap is sealed by a filler 39. Although, according to the prior art method, the package was produced by using the lead frame and the bonding wire, the semiconductor package shown in the drawing utilizes the connection wiring 43 made of the conductive fine particle paste in place of these wiring elements. The wiring surface of the package is covered with the insulating film 36.

FIG. 33 is a sectional view of the semiconductor package according to the invention produced without using the flip chip method. According to the prior art method, the semiconductor element was mounted onto the wiring substrate by the flip chip bonding method. However, in the semiconductor package shown in the drawing, the semiconductor element 10 is directly mounted to the wiring support comprising the connection wiring 34 formed from the conductive fine particle paste into a predetermined pattern according to the invention and the insulating resin 32 sealing each connection wiring 34. Further, external connection terminals (solder bumps) 35 are fitted.

FIG. 34 is a sectional view of VMT (virtual mount technology) board having the wiring structure of the invention assembled therein. Here, the term “VMT board” does not mean those boards in which components or parts are electrically connected onto the wiring board, and thus the forms of the electronic devices are not restricted by the shape of the wiring board. The VMT board means those wiring structures in which the electronic devices are constituted in arbitrary forms by the programmable packaging method using the production method of the wiring structure according to the invention previously explained.

The VMT board shown in FIG. 34 represents an example where the wiring structure of the invention was applied to those products (not shown) that have a three-dimensional curve such as a body of an automobile or a helmet. Though the VMT board shown in the drawing has a complicated construction, a desired board can be easily produced by repeating the steps of forming the connection wiring from the conductive fine particle paste on the surface of the free cell according to the invention. In other words, this VMT board can be produced by the steps of:

forming a free cell 12a and then forming a connection wiring 14a on the upper surface of the cell 12a by a printing method using the conductive fine particle paste;

forming a free cell 12b and then forming a connection wiring 14b on the upper surface of the cell 12b by the printing method using the conductive fine particle paste;

forming a free cell 12c and then forming a connection wiring 14c on the upper surface of the cell 12c by the printing method using the conductive fine particle paste;

forming a free cell 12d and then forming a connection wiring 14d on the upper surface of the cell 12d by the printing method using the conductive fine particle paste;

mounting two chip components 50 to predetermined positions;

forming a free cell 12e and then forming a connection wiring 14e on the upper surface of the cell 12e by the printing method using the conductive fine particle paste; and

sealing the board as a whole with an insulating resin 12f.

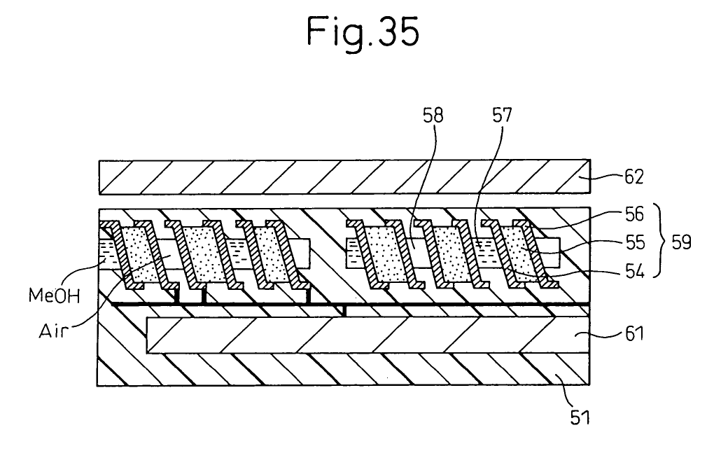

Further, FIG. 35 is a sectional view of a display VMT board having a built-in DMFC (Direct Methanol Fuel Cell) type fuel cell having the wiring structure of the invention assembled therein. Here, the term “DMFC type fuel cell” represents a fuel cell that directly supplies methanol as a fuel among polymer solid electrolyte type fuel cells or so-called “PEFC”.

Referring to the display VMT board shown in FIG. 35, a DMFC type fuel cell 59 and a semiconductor element (for example, LSI chip) 61 are mounted onto a substrate 51, and the fuel cell 59 and an image display unit (for example, liquid crystal display) 62 are electrically connected to each other through a wiring pattern (not shown). The fuel cell 59 comprises a wiring structure including an anode electrode wiring 54 formed of platinum or nano-carbon, for example, an electrolyte film 55 formed of perfluorosulfonic acid type polymer, a cathode electrode wiring 56 formed of platinum or nano-carbon, for example, an anode side channel 57 and a cathode side channel 58. Methanol (MeOH) is supplied as the fuel to the anode side channel 57 and air is supplied as an oxidizing agent to the cathode side channel 58.

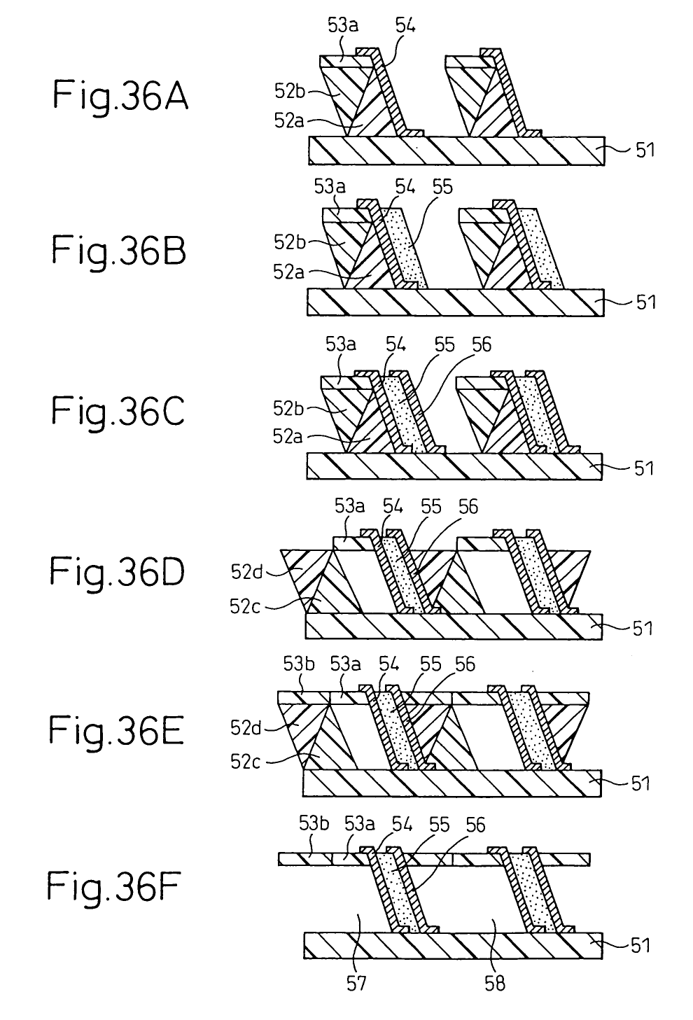

In the display VMT board shown in FIG. 35, the wiring structure can be advantageously produced as schematically shown in FIGS. 36A to 36F, for example, in accordance with the method of the invention. To simplify the explanation, the wiring structure shown in these drawings does not exactly correspond to the board shown in FIG. 35.

First, as shown in FIG. 36A, basic cells 52a and 52b are successively formed on an insulating resin substrate 51. These basic cells are dummy cell-like supports (dummy cells) that are removed in a subsequent step and are capable of forming a channel (flow path). The dummy cells have a triangular sectional shape. The basic cells are preferably formed of a fluorine-containing material such as Teflon™ or a silicone type material. Next, an insulating film 53a is formed of the same resin as that of the resin substrate 51 on the basic cell 52b, and the anode electrode wiring 54 is then formed in such a manner as to extend from the surface of the resin substrate 51, the surface of the basic cell 52a and the upper surface of the insulating film 53a. When the conductive fine particle paste according to the invention is used, the anode electrode wiring 54 can be formed easily and exactly by means such as the printing method.

Next, as shown in FIG. 36B, an electrolyte film 55 is formed adjacent to the anode electrode wiring formed in the preceding step. The electrolyte film 55 can be also formed easily and exactly by the printing method using the perfluorosulfonic acid type polymer according to the invention.

After the anode electrode wiring 54 and the electrolyte film 55 are formed as described above, the cathode electrode wiring 56 is formed in the same way as the anode electrode wiring 54 as shown in FIG. 36C.

Subsequently, to move on to the channel formation step, the basic cells 52a and 52b are removed and new basic cells 52c and 52d are applied as shown in FIG. 36D.

The insulating film 53b is formed on the upper surface of the basic cell 52d as shown in FIG. 36E. The insulating film 53b can be formed in the same way as the insulating film 53a.

Finally, when the basic cells 52c and 52d are moved transversely and removed, a wiring structure having the anode side channel 57 and the cathode side channel 58 can be obtained as shown in FIG. 36F. Though not shown in the drawings, wiring and the like (not shown) of the image display device can also be formed easily and accurately through the printing method of the conductive fine particle paste according to the invention.

### INDUSTRIAL APPLICABILITY

As described above, as the wirings are formed by using the fine conductive paste, the invention can easily form even extremely fine wirings. In comparison with the prior art case where the conductive paste is similarly used, the invention can form the wiring at a far higher density. The resulting connection wiring is free from disconnection and short-circuits that have been observed in the bonding wires of the prior art. Because the connection wiring is formed on the cell surface by the printing method and the like using the fine conductive paste, a variety of wirings can be formed easily, and the invention can be suitably utilized for the production of various composite products such as modules having various circuit components assembled therein besides the semiconductor elements. Furthermore, the invention can provide easily, and with a high yield, a wiring structure in which the fine wirings are dispersed with a high density.

1. A wiring structure comprising connection wiring for electrically connecting elements to one another or one element to another constituent element, wherein said connection wiring is a sintered product formed by depositing a paste of electrically conductive fine particles comprising electrically conductive fine particles having a particle diameter of 100 nm or below dispersed in a dispersant, on an electrically insulating base in accordance with a predetermined wiring pattern, and then sintering a wiring precursor so formed.

2. A wiring structure according to claim 1, wherein said connection wiring includes a wiring selected from the group consisting of wirings extending plane-wise, wirings extending three-dimensionally and wirings penetrating through an insulating film, or a combination of such wirings.

3. A wiring structure according to claim 1 or 2, wherein said electrically conductive fine particles in said conductive fine particle paste are fine particles of a metal selected from the group consisting of gold, silver, copper, platinum, nickel, palladium, tin or an oxide or alloy thereof.

4. A wiring structure according to any one of claims 1 to 3, wherein said wiring precursor is a deposited product formed by jetting said fine particle paste onto said base by an ink jet system, and depositing said fine particle paste at a predetermined thickness.

5. A wiring structure according to any one of claims 1 to 3, wherein said wiring precursor is a deposited product formed by the successively depositing said fine particle paste in the form of a fine tablet onto said base.

6. A wiring structure according to claim 5, wherein said tablet is formed by jetting said fine particle paste onto said base by an ink jet system.

7. A wiring structure according to claim 5, wherein said tablet is formed by discharging said fine particle paste onto said base, from a dispenser.

8. A wiring structure according to any one of claims 5 to 7, wherein said wiring precursor is a deposited product formed by the successively depositing said fine particle paste in the form of a fine tablet onto said base, and adjacent to said wiring precursor, an insulating film is formed by depositing tablets of a material having electrically insulating property.

9. A wiring structure according to any one of claims 1 to 8, wherein said base comprises one or more cell-like supports having a three-dimensional structure, and each of said supports is made of a material having electrically insulating property.

10. A wiring structure according to claim 9, wherein said cell-like support has an arbitrary configuration necessary for forming a desired wiring pattern.

11. A wiring structure according to claim 9, wherein each of said cell-like supports has a predetermined basic configuration, and a base necessary for forming a desired wiring pattern is provided upon combination of two or more of said supports.

12. A wiring structure according to any one of claims 9 to 11, which further comprises a cell-like support made of a dielectric material, a cell-like support made of a material capable of adjusting a heat conduction coefficient and/or a cell-like support made of a material capable of adjusting a thermal expansion coefficient, in combination with said cell-like supports made of the electrically insulating material.

13. A wiring structure according to any one of claims 1 to 12, which is assembled on or into a semiconductor device having at least one semiconductor element.

14. A wiring structure according to any one of claims 1 to 12, which is assembled on or into a multi-layered wiring substrate.

15. A method for producing a wiring structure comprising connection wiring for electrically connecting elements to one another or one element to another constituent element, which comprises the steps of:
depositing a paste of electrically conductive fine particle comprising electrically conductive fine particles having a particle diameter of 100 nm or below dispersed in a dispersant, on an electrically insulating base in accordance with a predetermined wiring pattern; and
heating and sintering a wiring precursor so formed at a predetermined temperature to form said connection wiring.

16. A method for producing a wiring structure according to claim 15, further comprising the step of depositing said conductive fine particle paste to any one of a surface of said base extending plane-wise, a surface of said base extending three-dimensionally or an opening formed in said base.

17. A method for producing a wiring structure according to claim 15 or 16, in which used as said conductive fine particle paste, a paste in which said conductive fine particles are fine particles of a metal selected from the group consisting of gold, silver, copper, platinum, nickel, palladium, tin or an oxide or alloy thereof.

18. A method for producing a wiring structure according to any one of claims 15 to 17, wherein said wiring precursor is formed by jetting said fine particle paste onto said base by an ink jet system, to form said wiring precursor having a predetermined thickness.

19. A method for producing a wiring structure according to any one of claims 15 to 18, wherein said wiring precursor is formed by successively depositing said fine particle paste in the form of a fine tablet onto said base.

20. A method for producing a wiring structure according to claim 19, wherein said tablet is formed by jetting said fine particle paste onto said base by an ink jet system.

21. A method for producing a wiring structure according to claim 19, wherein said fine particle paste is discharged onto said base from a dispenser to form said tablet.

22. A method for producing a wiring structure according to any one of claims 19 to 21, wherein said wiring precursor is formed by successively depositing said fine particle paste in the form of a fine tablet onto said base, and an insulating film is formed adjacent to said wiring precursor by depositing tablets of a material having electrically insulating property.

23. A method for producing a wiring structure according to any one of claims 15 to 22, wherein cell-like supports are formed from an electrically insulating material, and said base is formed by combining one or more of said cell-like supports.

24. A method for producing a wiring structure according to claim 23, wherein said cell-like support is formed to have a configuration necessary for forming a desired wiring pattern.

25. A method for producing a wiring structure according to claim 23, wherein each of said cell-like supports is formed in a predetermined basic configuration, and two ore more of said supports are combined to form said base necessary for forming a desired wiring pattern.

26. A method for producing a wiring structure according to any one of claims 23 to 25, in which a cell-like support made of a dielectric material, a cell-like support made of a material capable of adjusting a heat conduction coefficient and/or a cell-like support made of a material capable of adjusting a thermal expansion coefficient, is used in combination with said cell-like supports made of the electrically insulating material.

27. A method for producing a wiring structure according to any one of claims 15 to 26, wherein said wiring structure is produced in a production process of a semiconductor device having at least one semiconductor element.

28. A method for producing a wiring structure according to any one of claims 15 to 26, wherein said wiring structure is produced in a production process of a multi-layered wiring substrate.
